(19) United States
(12) Patent Application Publication
(10) Pub. No.: US 2026/0321545 A1
(43) Pub. Date: Oct. 15, 2026

(54) SUBSTRATE PROCESSING APPARATUS AND CONNECTOR ASSEMBLY

(71) Applicant: Tokyo Electron Limited, Tokyo (JP)

(72) Inventors: Tomoya KATO, Miyagi (JP); Kenichi KATO, Miyagi (JP); Kazuya MATSUMOTO, Miyagi (JP); Hirofumi OHTA, Miyagi (JP); Taira TAKASE, Miyagi (JP)

(21) Appl. No.: 19/684,045

(22) Filed: May 21, 2026

Related U.S. Application Data
(63) Continuation of application No. PCT/JP2024/040864, filed on Nov. 18, 2024.

(30) Foreign Application Priority Data
Dec. 1, 2023 (JP) 2023-204089

(51) Int. Cl. H01J 37/32

(52) U.S. Cl. CPC H01J 37/3244; H01J 2237/002

(57) ABSTRACT

A substrate processing apparatus is configured to process a substrate. The substrate processing apparatus includes a first member and a second member stacked on each other and having different thermal expansion coefficients; and a connector assembly extending parallel to a stacking direction of the first member and the second member and configured to connect the first member and the second member. The connector assembly includes a sliding member that is slidable in a direction orthogonal to the stacking direction in response to thermal expansion of at least one of the first member or the second member.

### CROSS-REFERENCE TO RELATED APPLICATIONS

This application is a continuation application of International Application No. PCT/JP2024/040864, filed on Nov. 18, 2024, and designated the U.S., which is based upon and claims priority to Japanese Patent Application No. 2023-204089, filed on Dec. 1, 2023, the entire contents of which are incorporated herein by reference.

### BACKGROUND

### Field of the Invention

The present disclosure relates to a substrate processing apparatus and a connector assembly.

### 2. Description of the Related Art

Japanese Patent Application Publication No. 2020-017697 discloses a substrate processing apparatus (film-forming apparatus) configured to perform plasma processing, such as film formation or the like, on a substrate. In this type of substrate processing apparatus, thermal expansion occurs in a member provided in a processing chamber due to the influence of a plasma during plasma processing.

### SUMMARY

According to an aspect of the present disclosure, a substrate processing apparatus configured to process a substrate is provided. The substrate processing apparatus includes: a first member and a second member stacked on each other and having different thermal expansion coefficients; and a connector assembly extending parallel to a stacking direction of the first member and the second member and configured to connect the first member and the second member. The connector assembly includes a sliding member that is slidable in a direction orthogonal to the stacking direction in response to thermal expansion of at least one of the first member or the second member.

### BRIEF DESCRIPTION OF THE DRAWINGS

FIG. 1 is a diagram illustrating an overall configuration of a plasma processing system including a substrate processing apparatus (plasma processing apparatus) according to an embodiment of the present disclosure.

FIG. 2 is an enlarged cross-sectional diagram illustrating a vicinity of an outer circumference of a shower head including a connector assembly.

FIG. 3A is a first enlarged diagram illustrating the connector assembly in a state in which a cooling plate is not thermally expanded.

FIG. 3B is a second enlarged diagram illustrating the connector assembly in a state in which the cooling plate is thermally expanded.

FIG. 4 is a third enlarged diagram illustrating the connector assembly in a state in which a ceiling member is thermally expanded.

FIG. 5 is an enlarged cross-sectional diagram illustrating the vicinity of the outer circumference of the shower head including a connector assembly according to a modified example of the present disclosure.

FIG. 6A is a first enlarged diagram illustrating the connector assembly according to the modified example in a state in which the cooling plate is not thermally expanded.

FIG. 6B is a second enlarged diagram illustrating the connector assembly according to the modified example in a state in which the cooling plate is thermally expanded.

### DETAILED DESCRIPTION OF THE DISCLOSURE

When a plurality of members have different thermal expansion coefficients, connector portions connecting these members receive stress caused by the difference in thermal expansion. Therefore, for a connector portion connecting members having different thermal expansion coefficients, there is a need for a structure capable of allowing for the difference in thermal expansion.

The present disclosure provides a technique of being able to stably connect a plurality of members having different thermal expansion coefficients.

Hereinafter, embodiments for carrying out the present disclosure will be described with reference to the drawings. In the drawings, the same components are denoted by the same reference signs, and thus duplicate descriptions may be omitted.

### Plasma Processing System

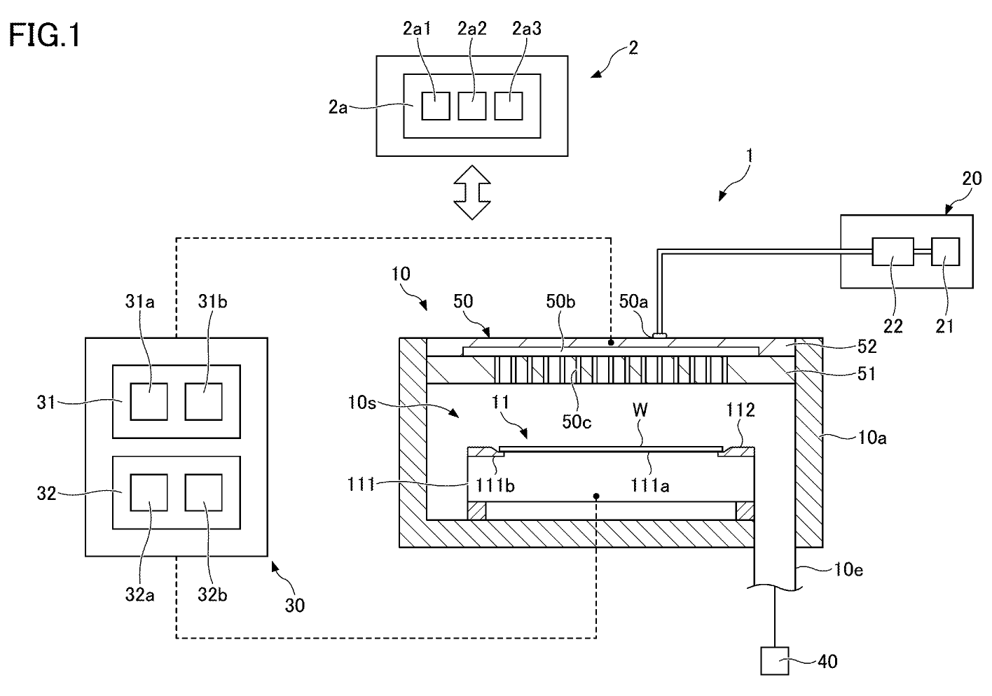

FIG. 1 is a diagram illustrating an overall configuration of a plasma processing system including a substrate processing apparatus (plasma processing apparatus 1) according to an embodiment. First, a configuration example of the plasma processing system will be described with reference to FIG. 1.

The plasma processing system includes the capacitively coupled plasma processing apparatus 1, which is the substrate processing apparatus, and a controller 2. The plasma processing apparatus 1 includes a plasma processing chamber 10, a gas supply 20, a power supply 30, and a gas discharge system 40. Also, the plasma processing apparatus 1 includes a substrate support 11 and a gas introducer. The gas introducer is configured to introduce at least one processing gas into the plasma processing chamber 10. The gas introducer includes a shower head 50. The substrate support 11 is disposed in the plasma processing chamber 10. The shower head 50 is disposed above the substrate support 11. In one embodiment, the shower head 50 forms at least a portion of the ceiling of the plasma processing chamber 10. The plasma processing chamber 10 includes a plasma processing space 10s defined by the shower head 50, a side wall 10a of the plasma processing chamber 10, and the substrate support 11. The plasma processing chamber 10 includes at least one gas supply port for supplying at least one processing gas into the plasma processing space 10s, and at least one gas outlet for discharging a gas from the plasma processing space. The side wall 10a is grounded. The shower head 50 and the substrate support 11 are electrically isolated from a housing of the plasma processing chamber 10.

The substrate support 11 includes a body 111 and a ring assembly 112. The body 111 includes a center region (substrate support surface) 111a configured to support a substrate (wafer) W, and an annular region (ring support surface) 111b configured to support the ring assembly 112. The annular region 111b of the body 111 encloses the center region 111a of the body 111 in a plan view. The substrate W is disposed on the center region 111a of the body 111, and the ring assembly 112 is disposed on the annular region 111b of the body 111 to enclose the substrate W on the center region 111a of the body 111. In one embodiment, the body 111 includes a base and an electrostatic chuck. The base includes a conductive member. The conductive member of the base functions as a lower electrode. The electrostatic chuck is disposed on the base. The upper surface of the electrostatic chuck includes the substrate support surface 111a. The ring assembly 112 includes one or more annular members. At least one of the one or more annular members is an edge ring. Also, although not illustrated, the substrate support 11 may include a temperature control module configured to adjust at least one of the electrostatic chuck, the ring assembly 112, or the substrate to a target temperature. The temperature control module may include a heater, a heat transfer medium, a flow path, or a combination of these. A heat transfer fluid, such as brine or gas, flows through the flow path. Also, the substrate support 11 may include a heat transfer gas supply configured to supply a heat transfer gas between the rear surface of the substrate W and the substrate support surface 111a.

The shower head 50 is configured to introduce at least one processing gas from the gas supply 20 into the plasma processing space 10s. The shower head 50 includes at least one gas supply port 50a, at least one gas diffusion chamber 50b, and a plurality of gas inlets 50c. The processing gas supplied to the gas supply port 50a passes through the gas diffusion chamber 50b, and is introduced into the plasma processing space 10s through the plurality of gas inlets 50c. Also, the shower head 50 includes a conductive member. The conductive member of the shower head 50 functions as an upper electrode.

The shower head 50 according to the embodiment has a stacked structure in which a plurality of members are stacked. The plurality of members of the shower head 50 include, for example, a ceiling member (first member) 51 forming a ceiling surface of the plasma processing space 10s, and a cooling plate (second member) 52 stacked on the upper portion of the ceiling member 51.

The ceiling member 51 is formed in a disk shape, and includes the plurality of gas inlets 50c along a plane direction (horizontal direction). Also, the ceiling member 51 according to the embodiment is formed as a conductive member (upper electrode) to which a source RF signal, a bias RF signal, or the like is to be supplied from the power supply 30, which will be described below. The ceiling member 51 is configured to generate a plasma from the processing gas in the plasma processing space 10s in accordance with a supplied source RF signal, a supplied bias RF signal, or the like. Therefore, the ceiling member 51 is formed of a material with conductivity. No particular limitation is imposed on the material of the ceiling member 51. Examples of the material of the ceiling member 51 include carbon (C: graphite or the like), silicon (Si), silicon carbide (SiC), or a combination of these materials.

The cooling plate 52 is formed in a disk shape with a recess, and is stacked on the upper surface of the ceiling member 51, thereby forming the gas diffusion chamber 50b at the boundary with the ceiling member 51. Also, the cooling plate 52 is provided in close contact with the ceiling member 51, and includes a cooling mechanism (not shown) in the cooling plate 52. Thus, heat of the ceiling member 51, which is heated by heat input from the plasma, is transferred to the cooling plate 52, and the ceiling member 51 can be cooled.

The cooling mechanism of the cooling plate 52 includes, for example, a spiral or annular coolant flow path (not shown) extending in a circumferential direction. The cooling mechanism is configured to circulate a low-temperature coolant from a chiller unit, provided outside the plasma processing chamber 10, by supplying and discharging the coolant to and from the coolant flow path of the cooling plate 52. As the coolant, cooling water, GALDEN (registered trademark), or the like is used. The cooling plate 52 is preferably formed of a material having high thermal conductivity for cooling the ceiling member 51. No particular limitation is imposed on the material of the cooling plate 52. Examples of the material include anodized aluminum, aluminum alloys, and the like. The gas introducer of the plasma processing chamber 10 may include, in addition to the shower head 50, one or more side gas injectors (SGI) attached to one or more openings formed in the side wall 10a.

The gas supply 20 may include at least one gas source 21 and at least one flow rate controller 22. In one embodiment, the gas supply 20 is configured to supply at least one processing gas from the gas source 21 to the shower head 50 via the corresponding flow rate controller 22. The flow rate controller 22 may include, for example, a mass flow controller or a pressure-controlled flow rate controller. Further, the gas supply 20 may include one or more flow rate modulation devices configured to modulate or pulse the flow rate of at least one processing gas.

The power supply 30 includes an RF power supply 31 connected to the plasma processing chamber 10 via at least one impedance matching circuit. The RF power supply 31 is configured to supply at least one RF signal (RF power), such as a source RF signal or a bias RF signal, to at least one of the conductive member of the substrate support 11 or the conductive member of the shower head 50. This forms a plasma from at least one processing gas supplied into the plasma processing space 10s. Therefore, the RF power supply 31 may function as at least part of a plasma generator configured to generate a plasma from one or more processing gases in the plasma processing chamber 10. Also, by supplying a bias RF signal to the conductive member of the substrate support 11, a bias potential is generated in the substrate W to enable ionic components in the formed plasma to be drawn into the substrate W.

In one embodiment, the RF power supply 31 includes a first RF generator 31a and a second RF generator 31b. The first RF generator 31a is connected to at least one of the conductive member of the substrate support 11 or the conductive member of the shower head 50 via at least one impedance matching circuit, and is configured to generate a source RF signal (source RF power) for plasma generation. In one embodiment, the source RF signal has a frequency in the range of 13 MHz to 150 MHz. In one embodiment, the first RF generator 31a may be configured to generate a plurality of source RF signals having different frequencies. The generated one or more source RF signals are supplied to at least one of the conductive member of the substrate support 11 or the conductive member of the shower head 50. The second RF generator 31b is connected to the conductive member of the substrate support 11 via at least one impedance matching circuit, and is configured to generate a bias RF signal (bias RF power). In one embodiment, the bias RF signal has a frequency lower than that of the source RF signal. In one embodiment, the bias RF signal has a frequency in the range of 400 kHz to 13.56 MHz. In one embodiment, the second RF generator 31b may be configured to generate a plurality of bias RF signals having different frequencies. The generated one or more bias RF signals are supplied to the conductive member of the substrate support 11. Also, in various embodiments, at least one of the source RF signal or the bias RF signal may be pulsed.

Also, the power supply 30 may include a DC power supply 32 connected to the plasma processing chamber 10. The DC power supply 32 includes a first DC generator 32a and a second DC generator 32b. In one embodiment, the first DC generator 32a is connected to the conductive member of the substrate support 11, and is configured to generate a first DC signal. The generated first bias DC signal is applied to the conductive member of the substrate support 11. In one embodiment, the first DC signal may be applied to other electrodes, such as electrodes in the electrostatic chuck. In one embodiment, the second DC generator 32b is connected to the conductive member of the shower head 50, and is configured to generate a second DC signal. The generated second DC signal is applied to the conductive member of the shower head 50. In various embodiments, at least one of the first or second DC signal may be pulsed. The first and second DC generators 32a and 32b may be provided in addition to the RF power supply 31, and the first DC generator 32a may be provided in place of the second RF generator 31b.

The gas discharge system 40 may be connected, for example, to a gas outlet 10e provided at the bottom of the plasma processing chamber 10. The gas discharge system 40 may include a pressure adjusting valve and a vacuum pump. The pressure adjusting valve is configured to adjust the internal pressure of the plasma processing space 10s. The vacuum pump may include a turbomolecular pump, a dry pump, or a combination of these.

The controller 2 processes computer-executable instructions that cause the plasma processing apparatus 1 to execute various steps described in the present disclosure. The controller 2 may be configured to control the components of the plasma processing apparatus 1 to execute various steps described herein. In one embodiment, a part or all of the controller 2 may be included in the plasma processing apparatus 1. The controller 2 may include, for example, a computer 2a. The computer 2a may include, for example, a processor (CPU: Central Processing Unit) 2a1, a storage 2a2, and a communication interface 2a3. The processor 2a1 may be configured to perform various control operations in accordance with a program stored in the storage 2a2. The storage 2a2 may include a RAM (Random Access Memory), a ROM (Read Only Memory), an HDD (Hard Disk Drive), an SSD (Solid State Drive), or a combination of these. The communication interface 2a3 may communicate with the plasma processing apparatus 1 via a communication line, such as a LAN (Local Area Network) or the like.

### Configuration of Shower Head 50 and Connector assembly 60

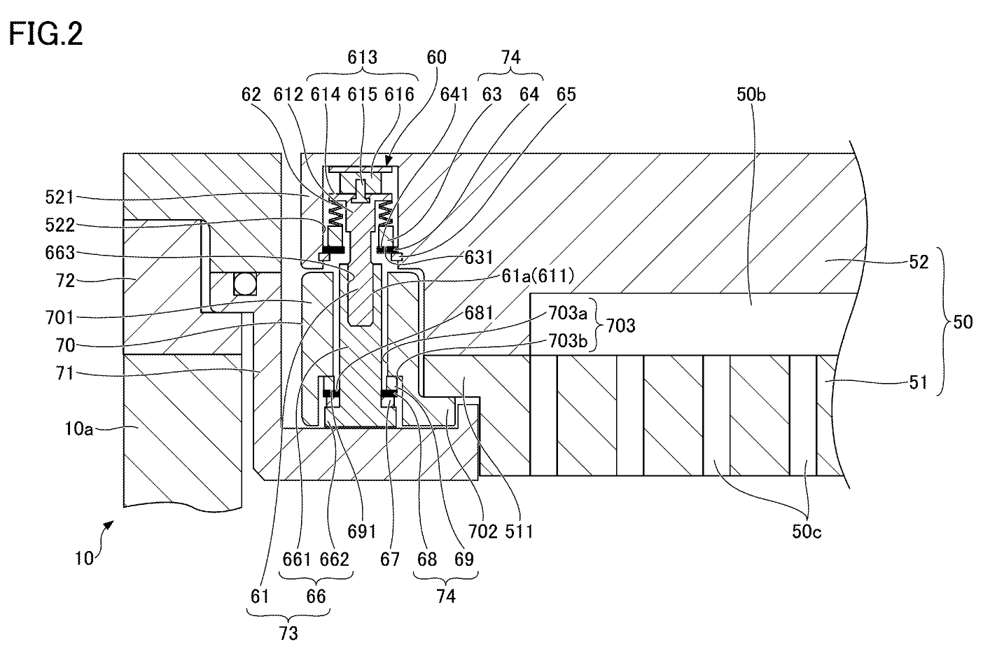

FIG. 2 is an enlarged cross-sectional diagram illustrating the vicinity of the outer circumference of the shower head 50 including the connector assembly 60. As illustrated in FIG. 2, the shower head 50 of the plasma processing apparatus 1 is disposed at an upper portion of the plasma processing chamber 10 in the form of a stack of the above plurality of members (the ceiling member 51 and the cooling plate 52). Therefore, the shower head 50 includes a plurality of connector assemblies 60, configured to connect the ceiling member 51 and the cooling plate 52, in the outer circumferential portions of the ceiling member 51 and the cooling plate 52.

The ceiling member 51 and the cooling plate 52 are formed of different materials, as described above. Therefore, the thermal expansion coefficient of the ceiling member 51 and the thermal expansion coefficient of the cooling plate 52 are different from each other. The connector assembly 60 has a clamping function to sandwich, and connect, the ceiling member 51 and the cooling plate 52 in an up-down direction (vertical direction). The shower head 50 may be formed by stacking other members, in addition to the ceiling member 51 and the cooling plate 52. In accordance with the shower head 50, the connector assembly 60 is not limited to a connector assembly configured to sandwich two members, and may be configured to sandwich three or more members.

Specifically, the ceiling member 51 of the shower head 50 includes an attaching step 511, configured to be engaged with the connector assembly 60, in the outer circumferential portion radially outward from the discharge surface including the plurality of gas inlets 50c. The attaching step 511 of the ceiling member 51 is formed to be thinner than the thickness of a discharge surface portion, and has an annular shape extending around the ceiling member 51.

The cooling plate 52 of the shower head 50 includes a projecting outer circumferential portion 521 that projects radially outward from the body in contact with the ceiling member 51. The projecting outer circumferential portion 521 is formed in an annular shape and positioned radially outward from the attaching step 511 of the ceiling member 51. A housing hole 522 for housing a portion (upper portion) of the connector assembly 60 is provided at a position next to a radially outward portion of the ceiling member 51 in the projecting outer circumferential portion 521. The housing hole 522 is provided in a number corresponding to the number of the connector assemblies 60 to be disposed, and arranged at intervals in the circumferential direction of the projecting outer circumferential portion 521.

The plurality of connector assemblies 60 each include a portion engaged with the attaching step 511 of the ceiling member 51, and a portion inserted into the housing hole 522 and engaged with the cooling plate 52, thereby clamping the ceiling member 51 and the cooling plate 52. Each connector assembly 60 clamps a plurality of circumferential portions of the ceiling member 51 and the cooling plate 52 to maintain an airtight state between the ceiling member 51 and the cooling plate 52. The shower head 50 may include an O-ring (not shown) or the like, configured to airtightly seal both the members, at the boundary between the ceiling member 51 and the cooling plate 52.

Each connector assembly 60 includes an external thread member 61, a disc spring 62, an elastic receiving member 63 (third member), an upper sliding seat member 64 (fourth member), a locking member 65, an internal thread member 66, a washer 67, a lower sliding seat member 68, a guiding member 69, and an internal thread holder 70. Also, the plasma processing chamber 10 includes a protective casing 71 covering the internal thread holder 70, and an insulating member 72 sandwiching the protective casing 71 between the insulating member 72 and the cooling plate 52.

The external thread member 61 is a member whose upper portion is housed in the housing hole 522 of the cooling plate 52 and whose lower portion, exposed from the housing hole 522, is inserted into the internal thread member 66. The external thread member 61 and the internal thread member 66 extend parallel to the stacking direction of the ceiling member 51 and the cooling plate 52, and form a fastened structure 73 in which they are threadedly engaged with each other. The clamping force of the connector assembly 60 with respect to the ceiling member 51 and the cooling plate 52 is variable according to the axial length of the external thread member 61 and the internal thread member 66 in the threaded engagement.

Specifically, the external thread member 61 includes a lower threaded portion 611 having, in the outer circumferential surface, a thread 61a to be threadedly engaged with the internal thread member 66; an intermediate rod 612 continuous with the upper end of the lower threaded portion 611; and a head 613 provided at the upper end of the intermediate rod 612. Also, the head 613 includes: a flange 614 projecting radially outward from the intermediate rod 612; a connector member 615 provided at the axial center of the intermediate rod 612; and a heat insulating member 616 connected to the connector member 615. The lower threaded portion 611, the intermediate rod 612, and the flange 614 are monolithically formed with each other.

The lower region of the lower threaded portion 611 is inserted into an internal thread hole 663 of the internal thread member 66, i.e., the lower region is a portion directly threadedly engaged with the internal thread member 66. The intermediate rod 612 has a smooth outer circumferential surface, and the disc spring 62 is disposed at its side circumference. The flange 614 is formed in an annular shape in a plan view, and functions as a seat configured to receive an elastic force of the disc spring 62. The connector member 615 is housed in a T-shaped hole, in a cross-sectional view, formed at the axial center of the intermediate rod 612, and slightly projects upward from the intermediate rod 612 in the vertical direction. The heat insulating member 616 covers the projecting connector member 615 and is fixed to the connector member 615, thereby suppressing transfer of heat from the cooling plate 52 to the external thread member 61.

The disc spring 62 is disposed between the elastic receiving member 63 and the flange 614 of the external thread member 61, and has a function to elastically receive a load (load in the direction parallel to the stacking direction) applied to both the members. For example, the connector assembly 60 includes a plurality of (five) disc springs 62 stacked in the vertical direction, and can relieve a large amount of load applied in the vertical direction. Also, the disc spring 62 can move integrally with the external thread member 61 by contacting the outer circumferential surface of the intermediate rod 612 of the external thread member 61.

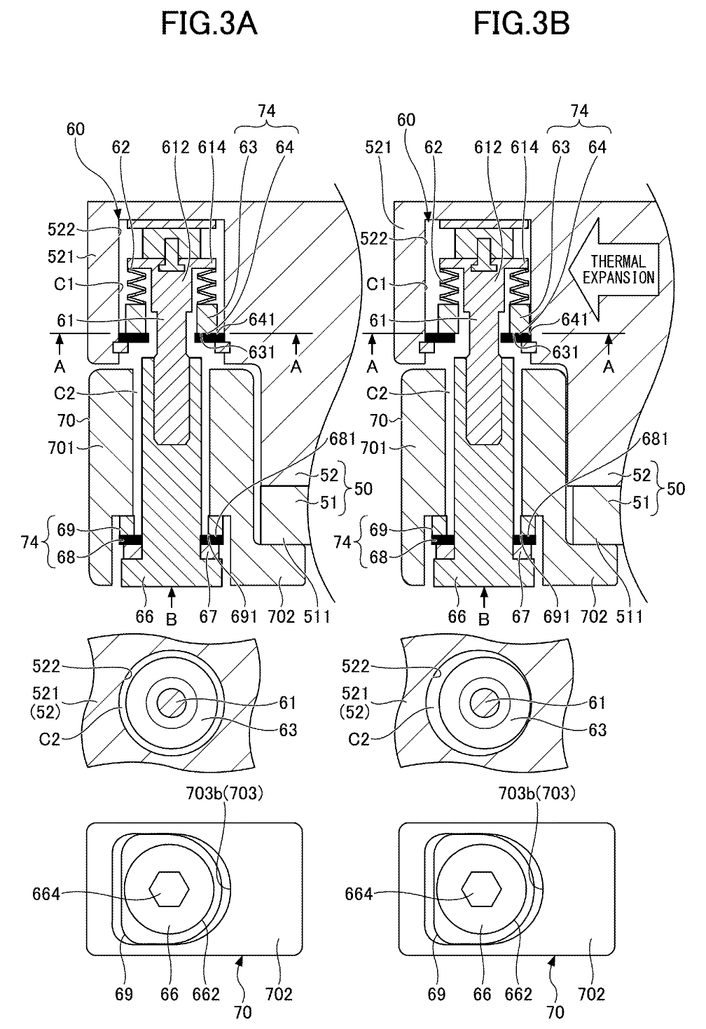

The elastic receiving member 63 is a tubular member disposed around the external thread member 61, and one end of the disc spring 62 is in contact with its upper end surface. The outer circumferential surface of the elastic receiving member 63 is formed to have an outer diameter slightly larger than the outer diameter of the flange 614 of the external thread member 61 or than the outer diameter of the disc spring 62. For example, the elastic receiving member 63 is preferably formed to have an outer diameter in the range of about 2/3 to about 9/10 of the inner diameter of the housing hole 522. Thus, an appropriate gap C1 is formed between the outer circumferential surface of the elastic receiving member 63 and the inner circumferential surface of the housing hole 522 (see FIG. 3A). The gap C1 enables the external thread member 61, the disc spring 62, and the elastic receiving member 63 to slide in the horizontal direction (the direction orthogonal to the stacking direction of the ceiling member 51 and the cooling plate 52).

The lower end surface of the elastic receiving member 63 is a flat (smooth) sliding surface 631 that extends in the horizontal direction, and is in contact with the upper sliding seat member 64. The sliding surface 631 enables the elastic receiving member 63 to slide relative to the upper sliding seat member 64.

The upper sliding seat member 64 is a member formed in an annular shape whose lower portion is supported by the locking member 65, and configured to support the elastic receiving member 63 to be movable relative to the upper sliding seat member 64. That is, the connector assembly 60 forms a sliding member 74, which is slidable in the horizontal direction orthogonal to the stacking direction, using the elastic receiving member 63 and the upper sliding seat member 64. The outer diameter of the upper sliding seat member 64 is nearly equal to the inner diameter of the housing hole 522. This maintains restriction of horizontal sliding of the upper sliding seat member 64 in the housing hole 522.

The upper surface of the upper sliding seat member 64 according to the embodiment is a flat (smooth) sliding surface 641 extending in the horizontal direction. However, the sliding member 74 is not limited to the sliding surface 631 of the elastic receiving member 63 and the sliding surface 641 of the upper sliding seat member 64, and can have various configurations. For example, one of the elastic receiving member 63 or the upper sliding seat member 64 of the sliding member 74 may be a sliding bearing configured to contact the sliding surface of the other and including a plurality of rolling elements capable of rolling.

The locking member 65 is formed in an annular shape in a plan view, and is fitted into an engagement groove formed in the inner circumferential surface of the housing hole 522. The locking member 65 can stably support the upper sliding seat member 64 by being non-detachably fixed to the cooling plate 52. In other words, the locking member 65 prevents the external thread member 61, the disc spring 62, the elastic receiving member 63, and the upper sliding seat member 64 from falling from the housing hole 522. In addition, the external thread member 61 can be elastically supported along the vertical direction.

The internal thread member 66 is a member to be threadedly engaged with the external thread member 61 in the connector assembly 60, and is formed to be thicker than the external thread member 61. The internal thread member 66 includes an internal thread body 661 extending in the vertical direction, and a flange head 662 continuous with the lower end of the internal thread body 661. The internal thread body 661 and the flange head 662 are monolithically formed with each other.

The internal thread body 661 extends in a straight line in the vertical direction, and is formed to be longer than the lower thread portion 611 of the external thread member 61. An opening of the internal thread hole 663 is provided at the upper end of the internal thread body 661. The internal thread hole 663 is formed to have a predetermined depth from the opening downward in the vertical direction, and a thread groove (not shown), with which the thread 61a of the external thread member 61 can be threadedly engaged, is formed in its inner circumferential surface. Also, the lower end surface of the internal thread body 661 is provided with a rotating hole 664 into which a wrench (not shown) (e.g., a hexagonal wrench) is inserted to rotate the internal thread member 66 (see FIG. 3A).

The flange head 662 slightly projects radially outward at the lower end of the internal thread body 661. A washer 67 is stacked on the upper surface of the flange head 662. The washer 67 is formed in an annular shape and supported by the flange head 662.

The lower sliding seat member 68 is formed in an annular shape, is supported by the washer 67, and is externally attached to the outer circumferential surface of the internal thread body 661. The inner diameter of the lower sliding seat member 68 is nearly equal to the outer diameter of the internal thread body 661. Thus, the lower sliding seat member 68 can move integrally with the internal thread member 66. Similar to the upper sliding seat member 64, the lower sliding seat member 68 slidably supports the guiding member 69 stacked on its upper surface.

The upper surface of the lower sliding seat member 68 according to the embodiment is a flat (smooth) sliding surface 681 extending in the horizontal direction. However, the sliding member 74 of the lower sliding seat member 68 and the guiding member 69 is not limited to this. For example, one of the lower sliding seat member 68 or the guiding member 69 may be a sliding bearing including a plurality of rolling elements.

The guiding member 69 is supported by the lower sliding seat member 68, and is externally attached to the outer circumferential surface of the internal thread body 661. However, the inner diameter of the guiding member 69 is formed to be larger than the outer diameter of the internal thread body 661, and thus a gap C2 is formed between the inner circumferential surface of the guiding member 69 and the outer circumferential surface of the internal thread body 661. The gap C2 allows for horizontal sliding of the internal thread holder 70 with respect to the internal thread body 661.

The guiding member 69 is formed in a D shape in a plan view, and is inserted into a through-hole 703 (lower hole 703b) of the internal thread holder 70, which is formed in a D shape (see FIG. 3A). Thus, the guiding member 69 can orient the internal thread holder 70 in a fixed direction.

The internal thread holder 70 is formed as a rectangular tubular member provided to face the housing hole 522 of the cooling plate 52, and configured to be engaged with the attaching step 511 of the ceiling member 51 while covering the side circumference of the internal thread member 66. Specifically, the internal thread holder 70 includes a holder 701, extending along the vertical direction over a length nearly equal to that of the internal thread member 66, and an engaging projection 702, projecting toward the ceiling member 51 on the lower side of the holder 701.

The through-hole 703, in which the internal thread member 66 is to be disposed, is formed inside the holder 701. The through-hole 703 includes: an upper hole 703a, in its upper portion, in which the internal thread body 661 is disposed; and a lower hole 703b, below the upper hole 703a, in which the flange head 662, the washer 67, the lower sliding seat member 68, and the guiding member 69 are disposed. The inner diameter of the upper hole 703a is formed to be larger than the outer diameter of the internal thread body 661 of the internal thread member 66, i.e., the gap C2 is formed. The lower hole 703b is formed in a D shape, and houses the guiding member 69.

The engaging projection 702 projects toward the ceiling member 51, and its upper surface contacts the attaching step 511 of the ceiling member 51. The connector assembly 60 can clamp the ceiling member 51 by adjusting the axial length of the external thread member 61 and the internal thread member 66 through threaded engagement to bring the engaging projection 702 into contact with the attaching step 511. That is, the connector assembly 60 sandwiches the ceiling member 51 and the cooling plate 52 between the locking member 65 connected to the cooling plate 52, and the internal thread holder 70 engaged with the ceiling member 51.

The protective casing 71 extends from the side wall 10a of the plasma processing chamber 10 to the ceiling member 51 of the shower head 50 to cover the connector assembly 60, thereby preventing the connector assembly 60 from being exposed to the plasma processing space 10s.

The insulating member 72 is provided between the shower head 50 (including the connector assembly 60) and the side wall 10a of the plasma processing chamber 10 to insulate the ceiling member 51, functioning as an upper electrode, from the side wall 10a. Thus, the plasma processing apparatus 1 can stably generate a plasma in the plasma processing space 10s in accordance with a signal supplied from the power supply 30 to the ceiling member 51.

### Operations of Plasma Processing Apparatus 1

The plasma processing apparatus 1 according to the embodiment is basically configured as described above, and its operations will be described below.

As illustrated in FIG. 1, the plasma processing apparatus 1 supplies a processing gas into the plasma processing space 10s of the plasma processing chamber 10 using the shower head 50. Also, the plasma processing apparatus 1 supplies a source RF signal or a bias RF signal from the power supply 30 to the shower head 50, thereby generating a plasma in the plasma processing space 10s. The shower head 50 receives heat of the plasma generated in the plasma processing space 10s. Here, the ceiling member 51 and the cooling plate 52 of the shower head 50 are formed of materials having different thermal expansion coefficients. Therefore, a difference in thermal expansion occurs between the ceiling member 51 and the cooling plate 52 due to heat input from the plasma.

Assuming that the ceiling member 51 and the cooling plate 52 are fastened by a screw (not shown), i.e., a simple structure, a difference in thermal expansion occurs between these to apply stress due to the thermal expansion to the ceiling member 51, the cooling plate 52, or the screw. When this stress is large, there is a risk that the ceiling member 51 and the cooling plate 52 are damaged, such as cracked or the like. In the plasma processing apparatus 1 according to the embodiment, the connector assembly 60 is applied for the connection between the ceiling member 51 and the cooling plate 52, as described above.

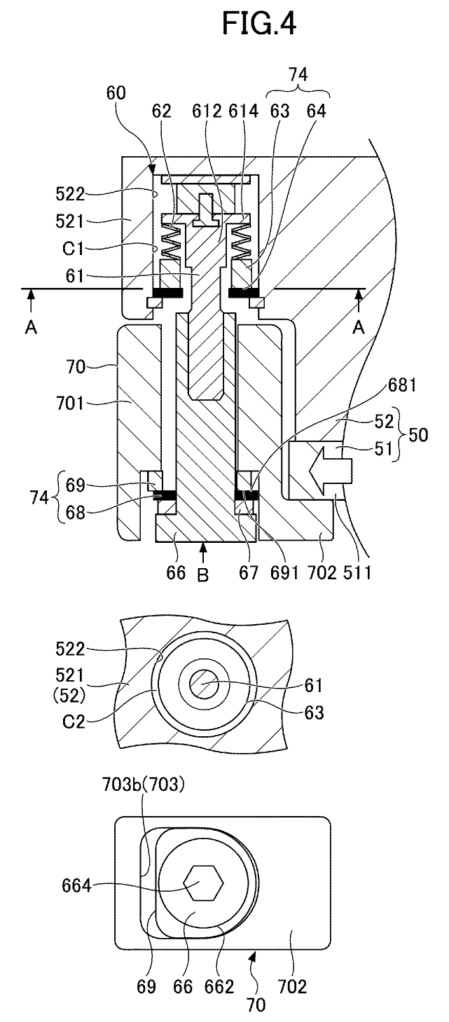

FIG. 3A is a first enlarged diagram illustrating the connector assembly 60 in a state in which the cooling plate 52 is not thermally expanded. FIG. 3B is a second enlarged diagram illustrating the connector assembly 60 in a state in which the cooling plate 52 is thermally expanded. FIG. 4 is a third enlarged diagram illustrating the connector assembly 60 in a state in which the ceiling member 51 is thermally expanded. In each of FIGS. 3A and 3B and 4, each intermediate diagram is a cross-sectional diagram taken along the line A-A in the upper diagram, and each lower diagram is a diagram as viewed from a direction indicated by an arrow B in the upper diagram.

As illustrated in FIG. 3A, in which no thermal expansion occurs in the shower head 50, the connector assembly 60 forms the gap C1 between: the inner circumferential surface of the housing hole 522 of the cooling plate 52; and the external thread member 61, the disc spring 62, and the elastic receiving member 63. The gap C1 in the connector assembly 60 allows for a relative movement of the external thread member 61, the disc spring 62, the elastic receiving member 63, and the like with respect to the upper sliding seat member 64 (and the locking member 65).

Similarly, the connector assembly 60 forms the gap C2 between: the internal thread member 66, the washer 67, and the lower sliding seat member 68; and the inner circumferential surface of the through-hole 703 of the guiding member 69 and the internal thread holder 70. The gap C2 in the connector assembly 60 allows for a relative movement of the guiding member 69 and the internal thread holder 70 with respect to the lower sliding seat member 68.

Even if the connector assembly 60 includes the gaps C1 and C2, the connector assembly 60 can firmly clamp the ceiling member 51 and the cooling plate 52 through threaded engagement between the external thread member 61 and the internal thread member 66. Specifically, the external thread member 61 housed in the housing hole 522 is engaged with the cooling plate 52 via the flange 614, the disc spring 62, the elastic receiving member 63, the upper sliding seat member 64, and the locking member 65. Thus, the connector assembly 60 applies a force to press the cooling plate 52 downward in the vertical direction. The internal thread member 66 is engaged with the attaching step 511 of the ceiling member 51 via the flange head 662, the washer 67, the lower sliding seat member 68, the guiding member 69, and the internal thread holder 70. Thus, the connector assembly 60 applies a force to press the ceiling member 51 upward in the vertical direction. Therefore, the connector assembly 60 can firmly clamp the ceiling member 51 and the cooling plate 52, thereby bringing both the members into close contact with each other. Even if heat from the plasma in the plasma processing space 10s is input into the ceiling member 51 during plasma processing, the shower head 50 can smoothly dissipate heat from the ceiling member 51 to the cooling plate 52.

Next, the case in which the cooling plate 52 is thermally expanded severely with respect to the ceiling member 51 will be described with reference to FIG. 3B. When the cooling plate 52 is thermally expanded, the projecting outer circumferential portion 521 provided radially outward from the cooling plate 52 is moved (swollen) radially outward. As a result, the locking member 65 inserted into the housing hole 522, and the upper sliding seat member 64 supported by the locking member 65 slide horizontally outward (radially outward from the cooling plate 52).

The elastic receiving member 63, which is in contact with the sliding surface 641 of the upper sliding seat member 64 at the sliding surface 631, does not follow the sliding of the upper sliding seat member 64 because the sliding surfaces 631 and 641 slide in the horizontal direction. Thus, the upper sliding seat member 64 slides relative to the elastic receiving member 63. As a result, the connector assembly 60 moves the locking member 65 and the upper sliding seat member 64 horizontally outward in response to thermal expansion of the cooling plate 52, while maintaining the positions of the elastic receiving member 63, the disc spring 62, the external thread member 61, and the like. Therefore, the inner portion of the gap C1 (a portion toward the center of the cooling plate 52) becomes smaller.

Since the external thread member 61 is not displaced through thermal expansion of the cooling plate 52, it is possible to maintain good threaded engagement with the internal thread member 66. The connector assembly 60 can suppress application of stress, due to the thermal expansion of the cooling plate 52, to the fastened structure 73, thereby avoiding damage to the connector assembly 60, damage to the ceiling member 51 or the cooling plate 52, or the like.

Next, the case in which the ceiling member 51 is thermally expanded with respect to the cooling plate 52 as illustrated in FIG. 4 will be described. For example, the ceiling member 51 may be thermally expanded, for example, when no heat exchange is performed in the cooling plate 52, or at the beginning of heat exchange. When the ceiling member 51 is thermally expanded, the attaching step 511 moves radially outward. Thus, the internal thread holder 70 engaged with the attaching step 511 slides in the horizontal direction (radially outward from the ceiling member 51).

Since the guiding member 69 of the internal thread holder 70 is in contact with the sliding surface 681 of the lower sliding seat member 68 via a sliding surface 691, the guiding member 69 moves relative to the lower sliding seat member 68. In other words, the internal thread member 66, the washer 67, and the lower sliding seat member 68 do not follow the sliding of the internal thread holder 70 or the guiding member 69. As a result, the connector assembly 60 can allow for the thermal expansion of the ceiling member 51, while reducing the inner portion of the gap C2 (a portion toward the center of the ceiling member 51).

For example, since the internal thread member 66 is not displaced through thermal expansion of the ceiling member 51, it is possible to maintain good threaded engagement with the external thread member 61. The connector assembly 60 can suppress application of stress, due to the thermal expansion of the ceiling member 51, to the fastened structure 73, thereby avoiding damage to the connector assembly 60, damage to the ceiling member 51 or the cooling plate 52, or the like.

As described above, since the connector assembly 60 includes the sliding member 74, it is possible to stably connect members having different thermal expansion coefficients. Moreover, since the sliding member 74 included in the connector assembly 60 includes a plurality of slidable sites (the site corresponding to the external thread member 61 and the site corresponding to the internal thread member 66), it is possible to appropriately allow for thermal expansion in accordance with the position of a member with large thermal expansion. Also, even if a large difference in thermal expansion occurs, the plurality of sliding members 74 can allow for the thermal expansion.

Also, by adjusting the axial length of the external thread member 61 and the internal thread member 66 in the threaded engagement, the connector assembly 60 can firmly bring the ceiling member 51 and the cooling plate 52 into contact with each other. Further, since the connector assembly 60 includes the sliding member 74 outside of the outer circumferential surface of the fastened structure 73 (the external thread member 61 and the internal thread member 66), it is possible to perform appropriate sliding in the sliding member 74, while maintaining the threaded engagement of the fastened structure 73. In particular, since the sliding member 74 is disposed at a position next to the internal thread member 66, it is possible to readily absorb a shearing force applied to the internal thread member 66 during thermal expansion. Moreover, since the sliding member 74 is disposed at a position next to the external thread member 61, it is possible to readily absorb a shearing force applied to the external thread member 61 during thermal expansion.

Since the sliding member 74 includes the two sliding surfaces 631 and 641 (or the sliding surfaces 681 and 691) that are in contact with each other, it is possible to perform sliding in the direction orthogonal to the stacking direction in a simple structure. Alternatively, when using a member with a rolling element in contact with the sliding surface, the sliding member 74 can perform sliding more smoothly.

The technique of the present disclosure is not limited to the above embodiment, and various modified examples are possible. Although the connector assembly 60 according to the embodiment connects the ceiling member 51 and the cooling plate 52 of the shower head 50 as an example, the connector assembly 60 may connect other members in the plasma processing chamber 10. Examples of the other members include, for example, the substrate support 11, a baffle plate, a shielding member, and the like, which are attached to the plasma processing chamber 10. Also, when the plasma processing chamber 10 is assembled by a plurality of members, the connector assembly 60 may be used as a connector for connection of the plasma processing chamber 10. Also, the connector assembly 60 may be applied to a substrate processing apparatus configured to perform heat processing without performing plasma processing.

Also, in the connector assembly 60 according to the embodiment, as an example, the external thread member 61 is arranged on the cooling plate 52 side, and the internal thread member 66 is arranged on the ceiling member 51 side. However, this arrangement may be reversed.

Also, in the connector assembly 60 according to the embodiment, the engaging projection 702 of the internal thread holder 70 is engaged with the attaching step 511 of the ceiling member 51. However, when the ceiling member 51 includes a hole with a configuration that is the same as that of the through-hole 703 described above, the ceiling member 51 can be fastened by the internal thread member 66 without using the internal thread holder 70. In this case, the washer 67, the lower sliding seat member 68, the guiding member 69, or the like may be interposed between the internal thread member 66 and the ceiling member 51.

### Modified Examples

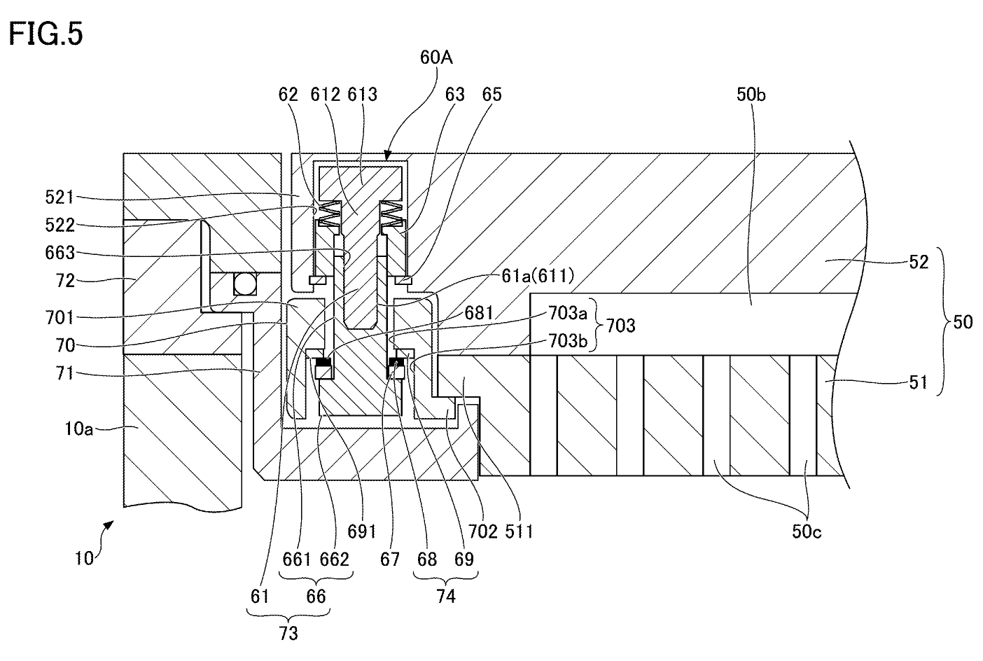

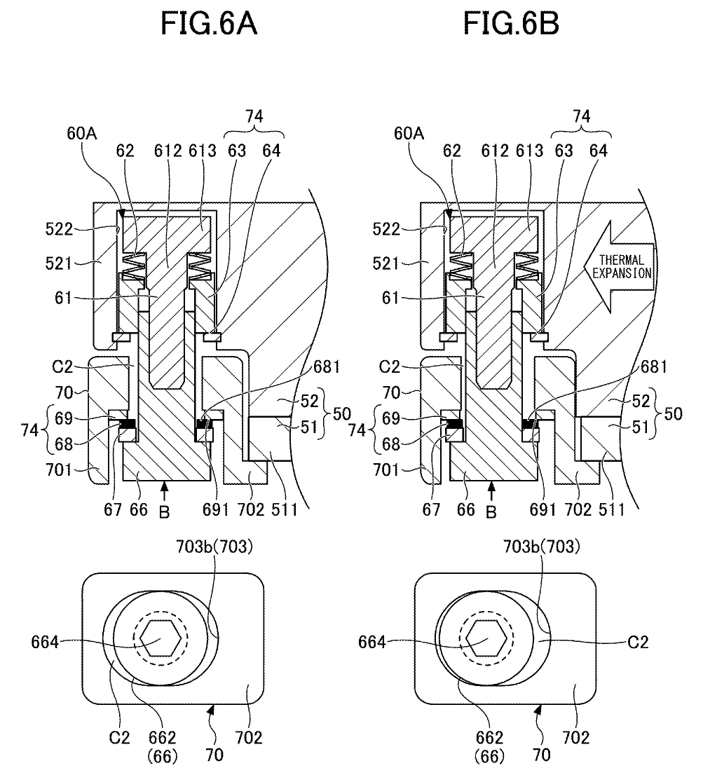

Next, a connector assembly 60A according to a modified example will be described with reference to FIGS. 5, 6A and 6B. FIG. 5 is an enlarged cross-sectional diagram illustrating the vicinity of the outer circumference of the shower head 50 including the connector assembly 60A according to the modified example. FIG. 6A is a first enlarged diagram illustrating the connector assembly 60A according to the modified example in a state in which the cooling plate 52 is not thermally expanded, and FIG. 6B is a second enlarged diagram illustrating the connector assembly 60A according to the modified example in a state in which the cooling plate 52 is thermally expanded. In each of FIGS. 6A and 6B, the lower diagram is a diagram as viewed from a direction indicated by an arrow B in the upper diagram.

The connector assembly 60A according to the modified example is different from the connector assembly 60 in that the sliding member 74 is provided at a position next to the internal thread member 66 (between the internal thread member 66 and the internal thread holder 70), while the sliding member 74 is not provided at a position next to the external thread member 61.

Specifically, the connector assembly 60A includes the external thread member 61, the disc spring 62, the elastic receiving member 63, the locking member 65, the internal thread member 66, the washer 67, the lower sliding seat member 68, the guiding member 69, and the internal thread holder 70. The internal thread member 66 is inserted into the elastic receiving member 63 in a state of being threadedly engaged with the external thread member 61 and disposed in the housing hole 522.

The external thread member 61 includes the lower threaded portion 611, the intermediate rod 612, and the head 613. One end of the disc spring 62 is in contact with the head 613 projecting radially outward, and the disc spring 62 is externally attached to the outer circumferential surface of the intermediate rod 612.

The elastic receiving member 63 is formed in a tubular shape extending along the vertical direction, and is supported by the locking member 65 fitted into the housing hole 522 on the lower side in the vertical direction. The elastic receiving member 63 includes a hole 63h into which the internal thread member 66 can be inserted from the lower side in the vertical direction. Also, the outer diameter of the elastic receiving member 63 is nearly equal to the inner diameter of the housing hole 522, and the gap C1 (see FIG. 3A) is not provided between the elastic receiving member 63 and the cooling plate 52. Thus, when the cooling plate 52 is thermally expanded, the elastic receiving member 63 and the internal thread member 66 move in the horizontal direction following the thermal expansion.

The internal thread member 66 includes the internal thread body 661 and the flange head 662. The upper end of the internal thread body 661 is inserted into the elastic receiving member 63, and housed in the housing hole 522. The washer 67 is supported by the flange head 662 of the internal thread member 66.

The lower sliding seat member 68 is formed in an annular shape, and includes the sliding surface 681 on its upper surface. The guiding member 69 includes the sliding surface 691, on its lower surface, in contact with the lower sliding seat member 68. That is, the connector assembly 60A forms the single sliding member 74 by the lower sliding seat member 68 and the guiding member 69.

The guiding member 69 is fixed to the internal thread holder 70. The internal thread holder 70 includes the holder 701 and the engaging projection 702. The internal thread holder 70 is engaged with the attaching step 511 of the ceiling member 51 via the engaging projection 702. Also, the through-hole 703 of the internal thread holder 70 includes an upper hole 703a and a lower hole 703b, and the gap C2 is formed between the through-hole 703 and the internal thread member 66. Further, the lower hole 703b of the through-hole 703 is formed as an elongated hole for moving the flange head 662 of the internal thread member 66 in one direction.

The connector assembly 60 according to the modified example is basically formed as described above, and its operations will be described below.

As illustrated in FIG. 6A, the connector assembly 60A firmly sandwiches the ceiling member 51 and the cooling plate 52 through threaded engagement between the external thread member 61 and the internal thread member 66. Specifically, the external thread member 61 is engaged with the cooling plate 52 via the flange 614, the disc spring 62, the elastic receiving member 63, and the locking member 65, thereby pressing the cooling plate 52 downward in the vertical direction. The internal thread member 66 is engaged with the projecting outer circumferential portion 521, i.e., the flange head 662, the washer 67, the lower sliding seat member 68, the guiding member 69, and the internal thread holder 70, thereby pressing the ceiling member 51 upward in the vertical direction. Therefore, the connector assembly 60A can firmly bring the ceiling member 51 and the cooling plate 52 into contact with each other.

When no thermal expansion occurs in the shower head 50, the connector assembly 60A forms the gap C2 between the outer circumferential surface of the internal thread member 66 (the internal thread body 661 and the flange head 662) and the inner circumferential surface of the through-hole 703 of the guiding member 69 and the internal thread holder 70.

As illustrated in FIG. 6B, in which the cooling plate 52 is thermally expanded, the projecting outer circumferential portion 521 moves radially outward, and the locking member 65 inserted into the housing hole 522 and the elastic receiving member 63 supported by the locking member 65 slide in the horizontal direction (radially outward from the cooling plate 52). Thus, the internal thread member 66 housed in the elastic receiving member 63 slides in the horizontal direction.

Further, the washer 67 and the lower sliding seat member 68 slide in response to the horizontal sliding of the internal thread member 66. The guiding member 69, which is in contact with the sliding surface 681 of the lower sliding seat member 68 via the sliding surface 691, does not follow the sliding of the lower sliding seat member 68. Thus, the lower sliding seat member 68 moves relative to the guiding member 69. As a result, the connector assembly 60A can allow for the thermal expansion of the cooling plate 52, while reducing the outer portion of the gap C2 (a portion farther away from the cooling plate 52).

For example, the internal thread member 66 can maintain a state of being non-displaced due to thermal expansion of the cooling plate 52. Therefore, it is possible to suppress application of stress, due to the thermal expansion of the cooling plate 52, to the fastened structure 73, thereby avoiding damage to the connector assembly 60A, damage to the ceiling member 51 or the cooling plate 52, or the like.

As described above, the connector assembly 60A according to the modified example can satisfactorily connect two members having different thermal expansion coefficients, and allow for a difference in thermal expansion between a plurality of members. In particular, since the connector assembly 60A includes the single sliding member 74, it is possible to simplify the structure and reduce the production cost.

The embodiments disclosed heretofore include, for example, the following.

[E1] A substrate processing apparatus configured to process a substrate, the substrate processing apparatus including:
a first member and a second member stacked on each other and having different thermal expansion coefficients; and
a connector assembly extending parallel to a stacking direction of the first member and the second member and configured to connect the first member and the second member, wherein
the connector assembly includes a sliding member that is slidable in a direction orthogonal to the stacking direction in response to thermal expansion of at least one of the first member or the second member.

[E2] The substrate processing apparatus according to [E1], wherein
the connector assembly includes an external thread member and an internal thread member extending in the stacking direction and configured to be threadedly engaged with each other, and
a clamping force with respect to the first member and the second member varies according to an axial length of the external thread member and the internal thread member in the threaded engagement.

[E3] The substrate processing apparatus according to [E2], wherein
the sliding member is provided outside of an outer circumferential surface of the external thread member and outside of an outer circumferential surface of the internal thread member.

[E4] The substrate processing apparatus according to [E2] or [E3], wherein
the sliding member is disposed at a position next to the internal thread member.

[E5] The substrate processing apparatus according to any one of [E2] to [E4], wherein
the external thread member is exposed from the internal thread member, and
the sliding member is disposed at a position next to the external thread member exposed from the internal thread member.

[E6] The substrate processing apparatus according to any one of [E1] to [E5], wherein
the connector assembly includes one or more additional sliding members that are slidable in the direction orthogonal to the stacking direction in response to the thermal expansion of at least one of the first member or the second member.

[E7] The substrate processing apparatus according to any one of [E1] to [E6], wherein
the sliding member brings sliding surfaces of a third member and a fourth member, which form the sliding member, into contact with each other, the sliding surfaces extending in the direction orthogonal to the stacking direction.

[E8] The substrate processing apparatus according to any one of [E1] to [E7], wherein
the sliding member brings a member including a sliding surface, extending in the direction orthogonal to the stacking direction, into contact with a member including a rolling element configured to contact the sliding surface.

[E9] The substrate processing apparatus according to any one of [E1] to [E8], wherein
the first member and the second member are provided in a plasma processing chamber including a plasma processing space in which a plasma is generated.

[E10] The substrate processing apparatus according to [E9], wherein
the first member and the second member form a shower head that is configured to discharge a processing gas into the plasma processing chamber and to which power for generating the plasma is to be supplied.

[E11] The substrate processing apparatus according to [E10], wherein
the first member is a ceiling member including a plurality of gas inlets for introducing the processing gas into the plasma processing space, and
the second member is a cooling plate provided vertically upward from the first member and configured to dissipate heat of the ceiling member.

[E12] A connector assembly configured to connect a first member and a second member provided in a substrate processing apparatus configured to process a substrate, the first member and the second member being stacked on each other and having different thermal expansion coefficients, wherein
the connector assembly extends parallel to a stacking direction of the first member and the second member, and includes a sliding member that is slidable in a direction orthogonal to the stacking direction in response to thermal expansion of at least one of the first member or the second member.

The substrate processing apparatus and the connector assemblies 60 and 60A according to the embodiments disclosed herein are illustrative in all respects and not limiting. The embodiments may be modified and improved in various ways without departing from the scope and intent of the claims recited. The matters described in the above embodiments can take other configurations, and can be combined as long as there is no contradiction.

The substrate processing apparatus of the present disclosure is applicable to an apparatus of any type, i.e., an Atomic Layer Deposition (ALD) apparatus, a Capacitively Coupled Plasma (CCP), an Inductively Coupled Plasma (ICP), a Radial Line Slot Antenna (RLSA), an Electron Cyclotron Resonance Plasma (ECR), and a Helicon Wave Plasma (HWP).

According to the aspect, it is possible to stably connect a plurality of members having different thermal expansion coefficients to each other.

What is claimed is:

1. A substrate processing apparatus configured to process a substrate, the substrate processing apparatus comprising:
a first member and a second member stacked on each other and having different thermal expansion coefficients; and
a connector assembly extending parallel to a stacking direction of the first member and the second member and configured to connect the first member and the second member, wherein
the connector assembly includes a sliding member that is slidable in a direction orthogonal to the stacking direction in response to thermal expansion of at least one of the first member or the second member.

2. The substrate processing apparatus according to claim 1, wherein
the connector assembly includes an external thread member and an internal thread member extending in the stacking direction and configured to be threadedly engaged with each other, and
a clamping force with respect to the first member and the second member varies according to an axial length of the external thread member and the internal thread member in the threaded engagement.

3. The substrate processing apparatus according to claim 2, wherein
the sliding member is provided outside of an outer circumferential surface of the external thread member and outside of an outer circumferential surface of the internal thread member.

4. The substrate processing apparatus according to claim 2, wherein
the sliding member is disposed at a position next to the internal thread member.

5. The substrate processing apparatus according to claim 2, wherein
the external thread member is exposed from the internal thread member, and
the sliding member is disposed at a position next to the external thread member exposed from the internal thread member.

6. The substrate processing apparatus according to claim 1, wherein
the connector assembly includes one or more additional sliding members that are slidable in the direction orthogonal to the stacking direction in response to the thermal expansion of at least one of the first member or the second member.

7. The substrate processing apparatus according to claim 1, wherein
the sliding member is configured to bring sliding surfaces of a third member and a fourth member, which form the sliding member, into contact with each other, the sliding surfaces extending in the direction orthogonal to the stacking direction.

8. The substrate processing apparatus according to claim 1, wherein
the sliding member is configured to bring a member including a sliding surface, extending in the direction orthogonal to the stacking direction, into contact with a member including a rolling element configured to contact the sliding surface.

9. The substrate processing apparatus according to claim 1, wherein
the first member and the second member are provided in a plasma processing chamber including a plasma processing space in which a plasma is generated.

10. The substrate processing apparatus according to claim 9, wherein
the first member and the second member form a shower head that is configured to discharge a processing gas into the plasma processing chamber and to which power for generating the plasma is to be supplied.

11. The substrate processing apparatus according to claim 10, wherein
the first member is a ceiling member including a plurality of gas inlets for introducing the processing gas into the plasma processing space, and
the second member is a cooling plate provided vertically upward from the first member and configured to dissipate heat of the ceiling member.

12. A connector assembly configured to connect a first member and a second member provided in a substrate processing apparatus configured to process a substrate, the first member and the second member being stacked on each other and having different thermal expansion coefficients, wherein
the connector assembly extends parallel to a stacking direction of the first member and the second member, and includes a sliding member that is slidable in a direction orthogonal to the stacking direction in response to thermal expansion of at least one of the first member or the second member.
